(19) United States
(12) Patent Application Publication
(10) Pub. No.: US 2014/0238644 A1
(43) Pub. Date: Aug. 28, 2014

(54) HEAT DISSIPATING DEVICE AND METHOD OF MANUFACTURING THE SAME

(71) Applicant: COOLER MASTER CO., LTD., New Taipei City (TW)

(72) Inventors: Tsung-Hsien Hsieh, New Taipei City (TW); Yu-Chin Liu, New Taipei City (TW)

(73) Assignee: COOLER MASTER CO., LTD., New Taipei City (TW)

(21) Appl. No.: 13/773,661

(22) Filed: Feb. 22, 2013

(51) Int. Cl. H05K 7/20

(52) U.S. Cl. CPC H05K 7/20009
USPC 165/104.21; 29/890.032

(57) ABSTRACT

A method of manufacturing a heat dissipating device includes steps of providing a base, wherein the base includes a clamping portion, a supporting portion and two side portions, the clamping portion is arc-shaped, a first recess structure is formed on an outer surface toward an inner surface of each side portion, the two side portions connect the clamping portion and the supporting portion, and an accommodating space is formed between the clamping portion, the supporting portion and the two side portions; disposing a first end of a heat pipe in the accommodating space, wherein the first end is supported on the supporting portion; and punching the clamping portion toward the supporting portion such that the clamping portion cooperates with the supporting portion to clamp the first end in a tight-fitting manner, wherein the clamping portion is capable of deforming through the first recess structure during punch processing.

### BACKGROUND OF THE INVENTION

1. Field of the Invention

The invention relates to a heat dissipating device and a method of manufacturing the same and, more particularly, to a heat dissipating device clamping a heat pipe in a base in a tight-fitting manner through a punch process and a method of manufacturing the heat dissipating device.

2. Description of the Prior Art

Heat dissipating device is a significant component for electronic products. When an electronic product is operating, the current in circuit will generate unnecessary heat due to impedance. If the heat is accumulated in the electronic components of the electronic product without dissipating immediately, the electronic components may get damage due to the accumulated heat. Therefore, the performance of heat dissipating device is a significant issue for the electronic product.

In general, most of the heat dissipating devices are equipped with heat pipes for conducting heat from electronic components to a heat sink and then the heat is dissipated out of the electronic product by the heat sink. So far a base of the conventional heat dissipating device, which is used for carrying the heat pipe, has to be processed by several processes and it wastes much time in transporting the base to each process such that production efficiency will decrease and production cost will increase.

### SUMMARY OF THE INVENTION

The invention provides a heat dissipating device clamping a heat pipe in abase in a tight-fitting manner through a punch process and a method of manufacturing the heat dissipating device, so as to solve the aforesaid problems.

According to an embodiment of the invention, a heat dissipating device comprises a base and a heat pipe. The base comprises a clamping portion, a supporting portion and two side portions, wherein a first recess structure is formed on an outer surface toward an inner surface of each side portion, the clamping portion is opposite to the supporting portion, the two side portions connect the clamping portion and the supporting portion, and an accommodating space is formed between the clamping portion, the supporting portion and the two side portions. A first end of the heat pipe is disposed in the accommodating space and supported on the supporting portion. The clamping portion cooperates with the supporting portion to clamp the first end of the heat pipe in a tight-fitting manner.

According to another embodiment of the invention, a method of manufacturing a heat dissipating device comprises steps of providing a base, wherein the base includes a clamping portion, a supporting portion and two side portions, the clamping portion is arc-shaped, a first recess structure is formed on an outer surface toward an inner surface of each side portion, the clamping portion is opposite to the supporting portion, the two side portions connect the clamping portion and the supporting portion, and an accommodating space is formed between the clamping portion, the supporting portion and the two side portions; disposing a first end of a heat pipe in the accommodating space, wherein the first end is supported on the supporting portion; and punching the clamping portion toward the supporting portion such that the clamping portion cooperates with the supporting portion to clamp the first end in a tight-fitting manner, wherein the clamping portion is capable of deforming through the first recess structure during punch processing.

As mentioned in the above, the base of the seat dissipating device of the invention can be formed by an aluminum extrusion process and the invention clamps the heat pipe in the base in a tight-fitting manner through a punch process. Since the first recess structure is formed on the outer surface toward the inner surface of each side portion, the clamping portion is capable of deforming through the first recess structure during punch processing accordingly. The process of the invention is simple and the efficiency of manufacturing the heat dissipating device can be improved effectively so that the manufacture cost can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart illustrating a method of manufacturing a heat dissipating device according to an embodiment of the invention.

FIG. 2 is a perspective view illustrating a heat dissipating device before assembly according to an embodiment of the invention.

FIG. 3 is a perspective view illustrating the heat dissipating device shown in FIG. 2 after assembly.

FIG. 4 is a front view illustrating the heat dissipating device shown in FIG. 3.

FIG. 5 is a front view illustrating a clamping portion of a base of the heat dissipating device shown in FIG. 4 after punch processing.

FIG. 6 is a perspective view illustrating a heat dissipating device before assembly according to another embodiment of the invention.

FIG. 7 is a front view illustrating the heat dissipating device shown in FIG. 6 after assembly, wherein the clamping portion of the base has been punched.

FIG. 8 is a perspective view illustrating a heat dissipating device before assembly according to another embodiment of the invention.

FIG. 9 is a perspective view illustrating the heat dissipating device shown in FIG. 8 after assembly.

FIG. 10 is a front view illustrating the heat dissipating device shown in FIG. 9.

FIG. 11 is a front view illustrating a clamping portion of a base of the heat dissipating device shown in FIG. 10 after punch processing.

FIG. 12 is a perspective view illustrating a heat dissipating device before assembly according to another embodiment of the invention.

FIG. 13 is a front view illustrating the heat dissipating device shown in FIG. 6 after assembly, wherein the clamping portion of the base has been punched.

### DETAILED DESCRIPTION

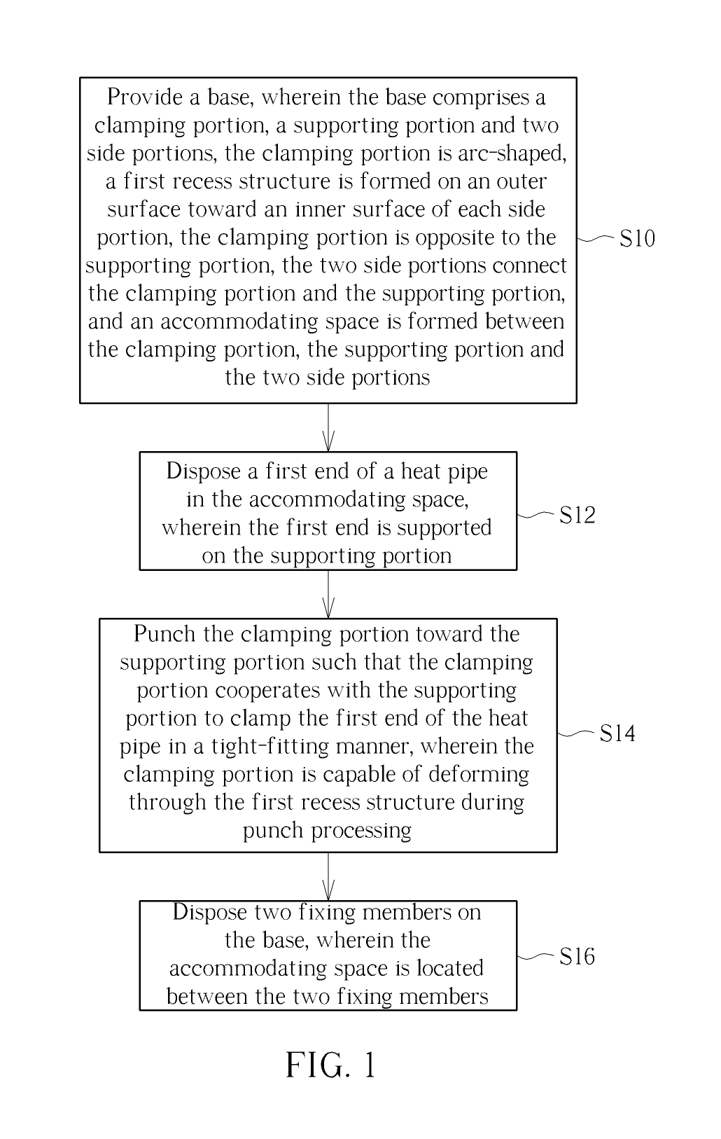

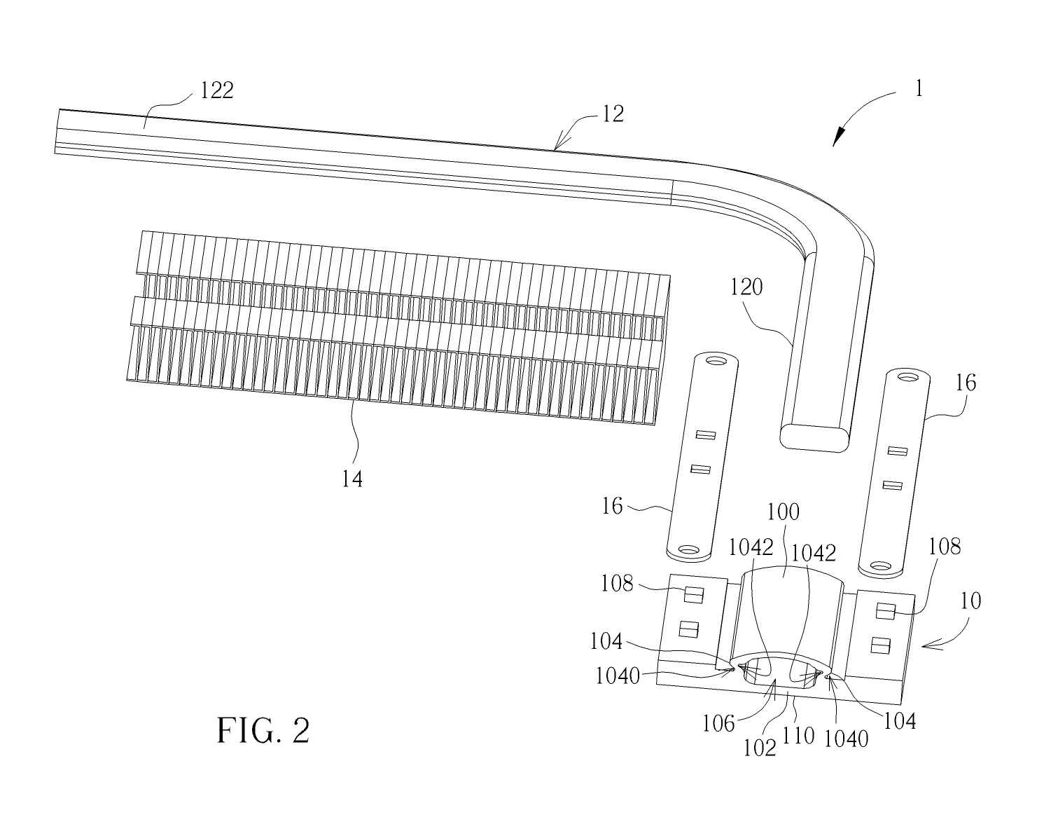

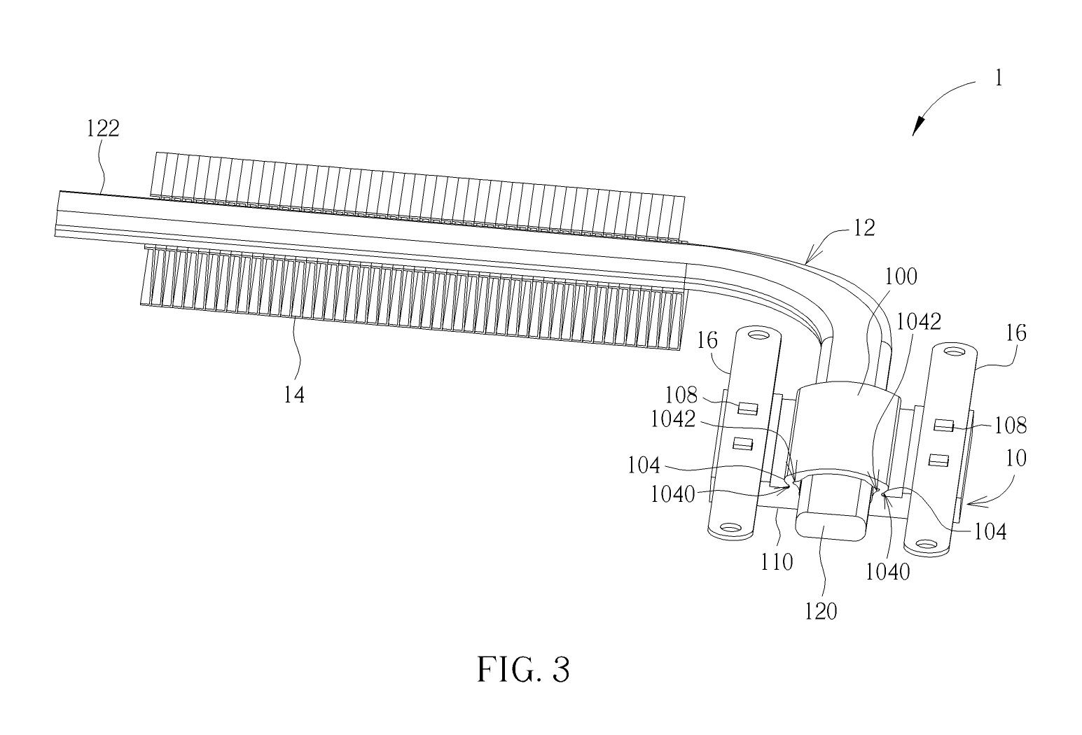

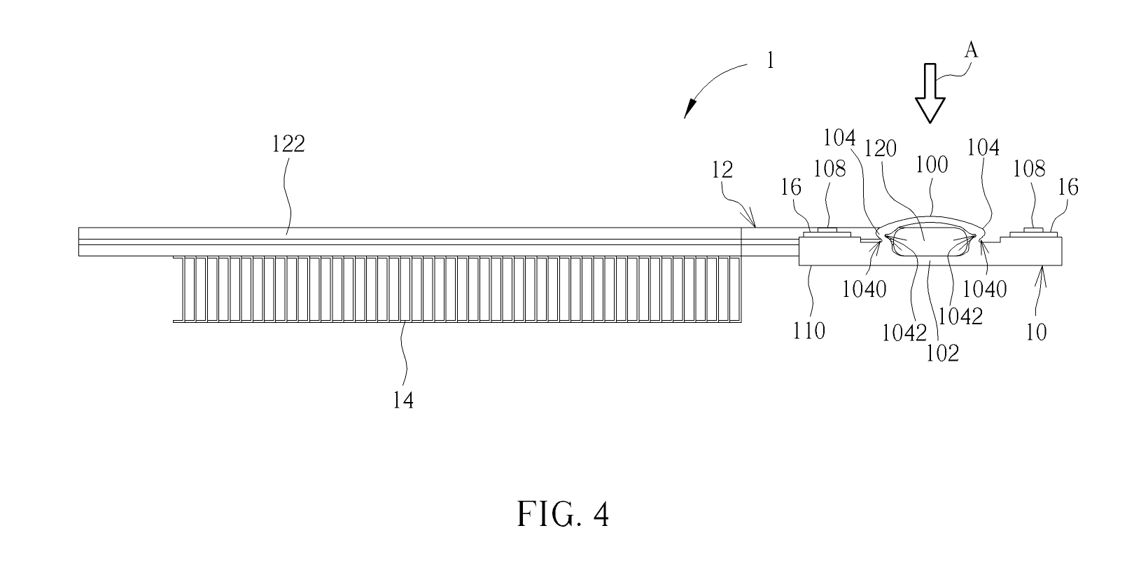

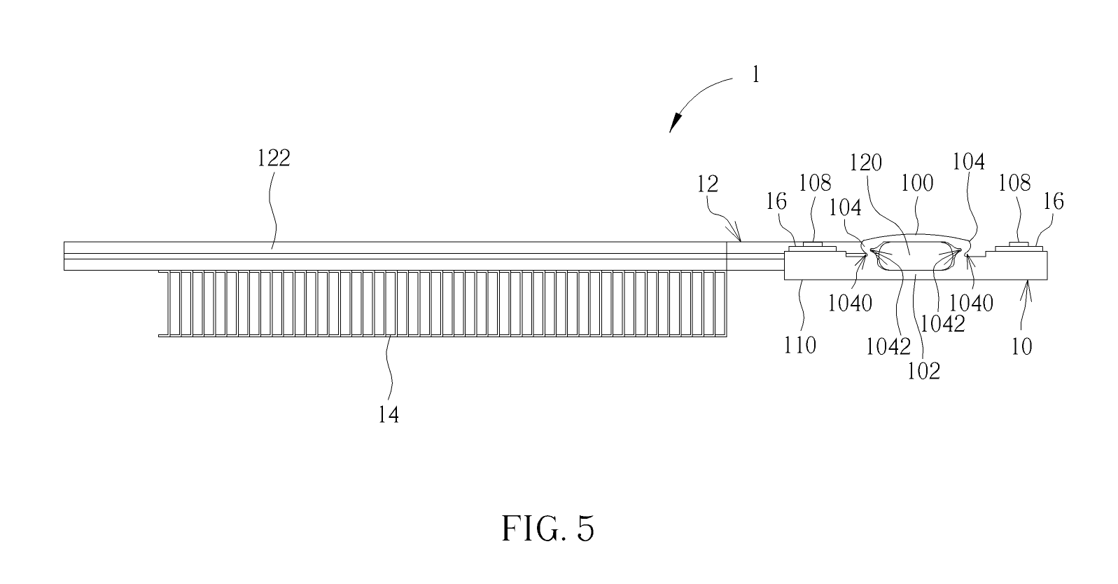

Referring to FIGS. 1 to 5, FIG. 1 is a flowchart illustrating a method of manufacturing a heat dissipating device according to an embodiment of the invention, FIG. 2 is a perspective view illustrating a heat dissipating device 1 before assembly according to an embodiment of the invention, FIG. 3 is a perspective view illustrating the heat dissipating device 1 shown in FIG. 2 after assembly, FIG. 4 is a front view illustrating the heat dissipating device 1 shown in FIG. 3, and FIG. 5 is a front view illustrating a clamping portion 100 of a base 10 of the heat dissipating device 1 shown in FIG. 4 after punch processing.

First of all, step S10 is performed to provide a base 10, wherein the base 10 comprises a clamping portion 100, a supporting portion 102 and two side portions 104, the clamping portion 100 is arc-shaped, a first recess structure 1040 is formed on an outer surface toward an inner surface of each side portion 104 such that the outer surface of each side portion 104 is S-shaped or Z-shaped, a second recess structure 1042 is formed on the inner surface toward the outer surface of each side portion 104, the clamping portion 100 is opposite to the supporting portion 102, the two side portions 104 connect the clamping portion 100 and the supporting portion 102, and an accommodating space 106 is formed between the clamping portion 100, the supporting portion 102 and the two side portions 104. In this embodiment, the base 10 can be formed by an aluminum extrusion process so as to simplify the manufacture process of the base 10. Accordingly, the manufacture efficiency can be improved and the manufacture cost can be reduced effectively.

Afterwards, step S12 is performed to dispose a first end 120 of a heat pipe 12 in the accommodating recess 106 of the base 10 such that the first end 120 is supported on the supporting portion 102 and dispose a heat sink 14 on a second end 122 of the heat pipe 12. In this embodiment, the heat pipe 12 is a flat heat pipe. However, in another embodiment, the heat pipe 12 may be a circular heat pipe or other heat pipes and it depends on practical applications. Furthermore, the heat sink 14 may consist of, but not limited to, a plurality of heat dissipating fins.

Step S14 is then performed to punch the clamping portion 100 of the base 10 toward the supporting portion 102 (as the direction indicated by an arrow A shown in FIG. 4) such that the clamping portion 100 deforms and cooperates with the supporting portion 102 to clamp the first end 120 of the heat pipe 12 in a tight-fitting manner, as shown in FIG. 5. Since the first recess structure 1040 and the second recess structure 1042 are formed on the outer surface and the inner surface of each side portion 104 respectively, the clamping portion 100 is capable of deforming through the first recess structure 1040 and the second recess structure 1042 during punch processing. In other words, after punching the clamping portion 100, the clamping portion 100 will extend toward the two side portions 104 so as to contact the first end 120 of the heat pipe 12 tightly. Consequently, the clamping portion 100 cooperates with the supporting portion 102 to clamp the first end 120 of the heat pipe 12 in a tight-fitting manner. In this embodiment, a thickness of the clamping portion 100 may be between, but not limited to, 0.6 mm and 1 mm such that the clamping portion 100 has high extensibility and will not crack during punch processing.

Finally, step S16 is performed to dispose two fixing members 16 on the base 10, wherein the accommodating space 106 is located between the two fixing members 16. In practical applications, the fixing members 16 may be, but not limited to, metal resilient plates. In this embodiment, the fixing members 16 may be riveted on the riveting portions 108 of the base 10. Furthermore, if there are no riveting portions 108 formed on the base 10, the fixing member 16 may be disposed on the base 10 by screws, soldering or other fixing manners.

Therefore, a heat dissipating device 1 shown in FIG. 5 can be manufactured through the aforesaid steps S10 to S16. In practical applications, a bottom surface 110 of the base 10 can be attached to an electronic component (not shown) and then the fixing members 16 can be fixed on a circuit board of an electronic product (not shown) so as to dissipate heat from the electronic component.

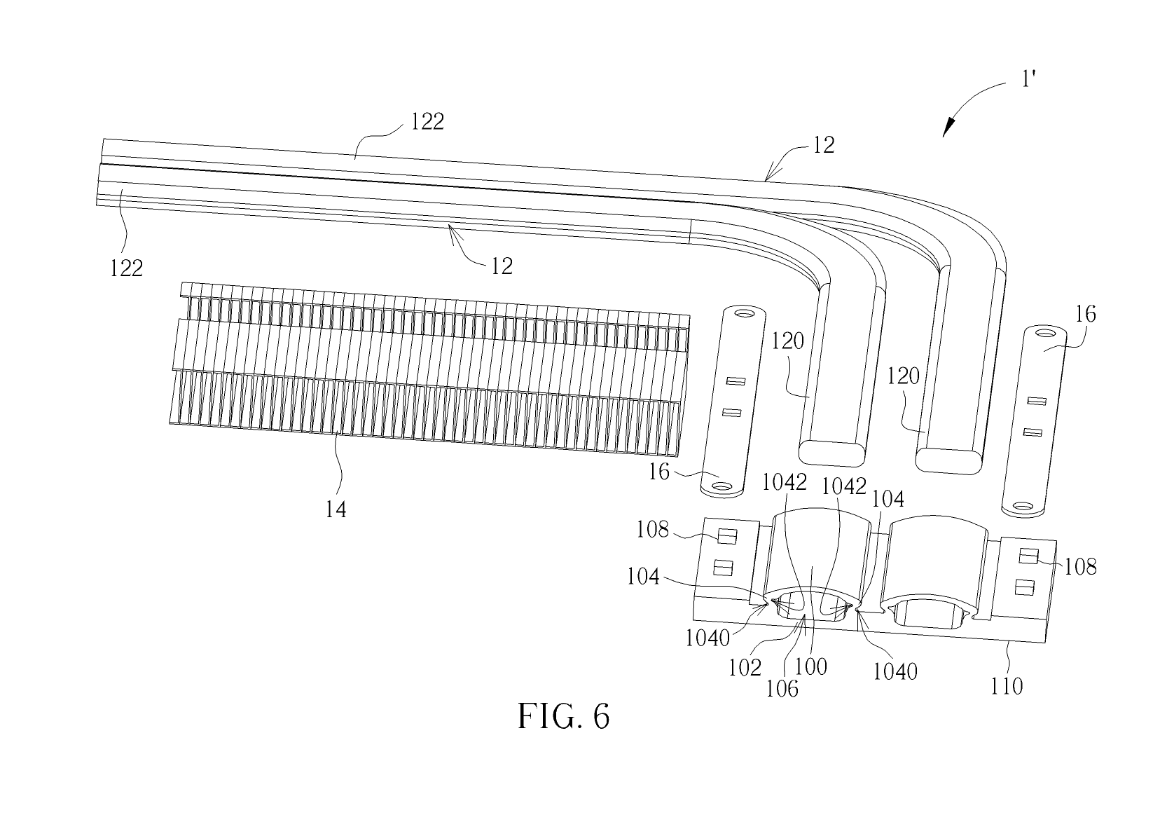

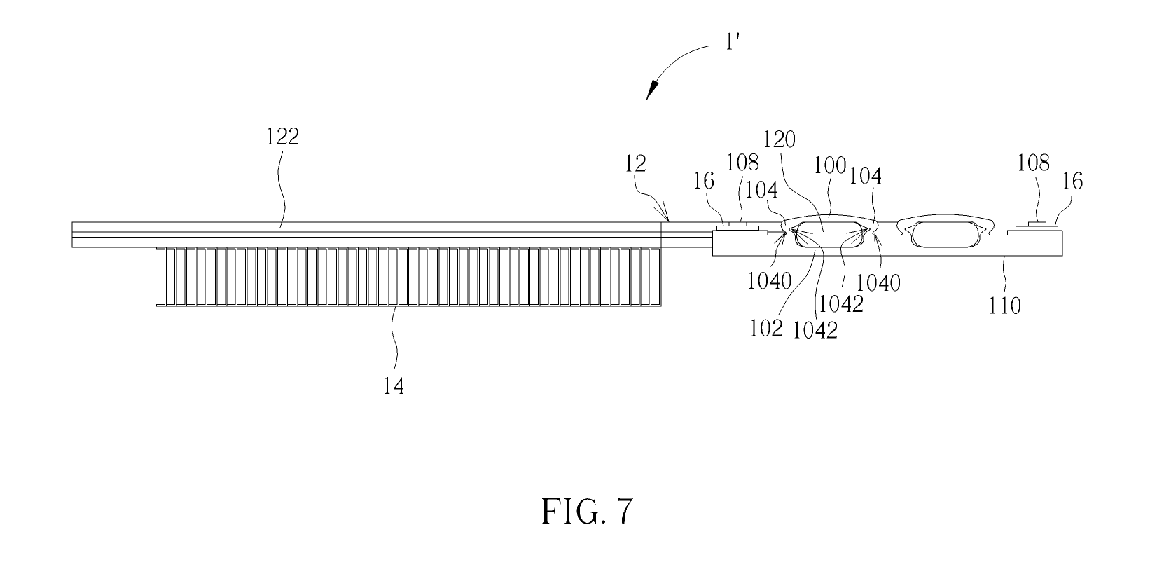

Referring to FIGS. 6 and 7 along with FIGS. 2 to 5, FIG. 6 is a perspective view illustrating a heat dissipating device 1′ before assembly according to another embodiment of the invention, and FIG. 7 is a front view illustrating the heat dissipating device 1′ shown in FIG. 6 after assembly, wherein the clamping portion 100 of the base 10′ has been punched. The difference between the heat dissipating device 1′ and the aforesaid heat dissipating device 1 is that the base 10′ of the heat dissipating device 1′ comprises two clamping portions 100, two supporting portions 102 and four side portions 104 with two accommodating spaces 106 formed therein, and the heat dissipating device 1′ comprises two heat pipes 12, as shown in FIGS. 6 and 7. The first end 120 of each heat pipe 12 can be disposed in the accommodating space 106 correspondingly through the aforesaid step S12 and then the two clamping portions 100 are punched through the aforesaid step S14, such that the two clamping portions 100 cooperate with the two supporting portions 102 to clamp the first ends 120 of the two heat pipes 12 in a tight-fitting manner, as shown in FIG. 7. In other words, the invention may form a plurality of clamping portions 100, supporting portions 102 and side portions 104 on the base 10′ by the aluminum extrusion process according to practical applications and then clamp a plurality of heat pipes 12 between the clamping portions 100 and the supporting portions 102 in a tight-fitting manner by punch processing. It should be noted that the same elements in FIGS. 6-7 and FIGS. 2-5 are represented by the same numerals, so the repeated explanation will not be depicted herein again.

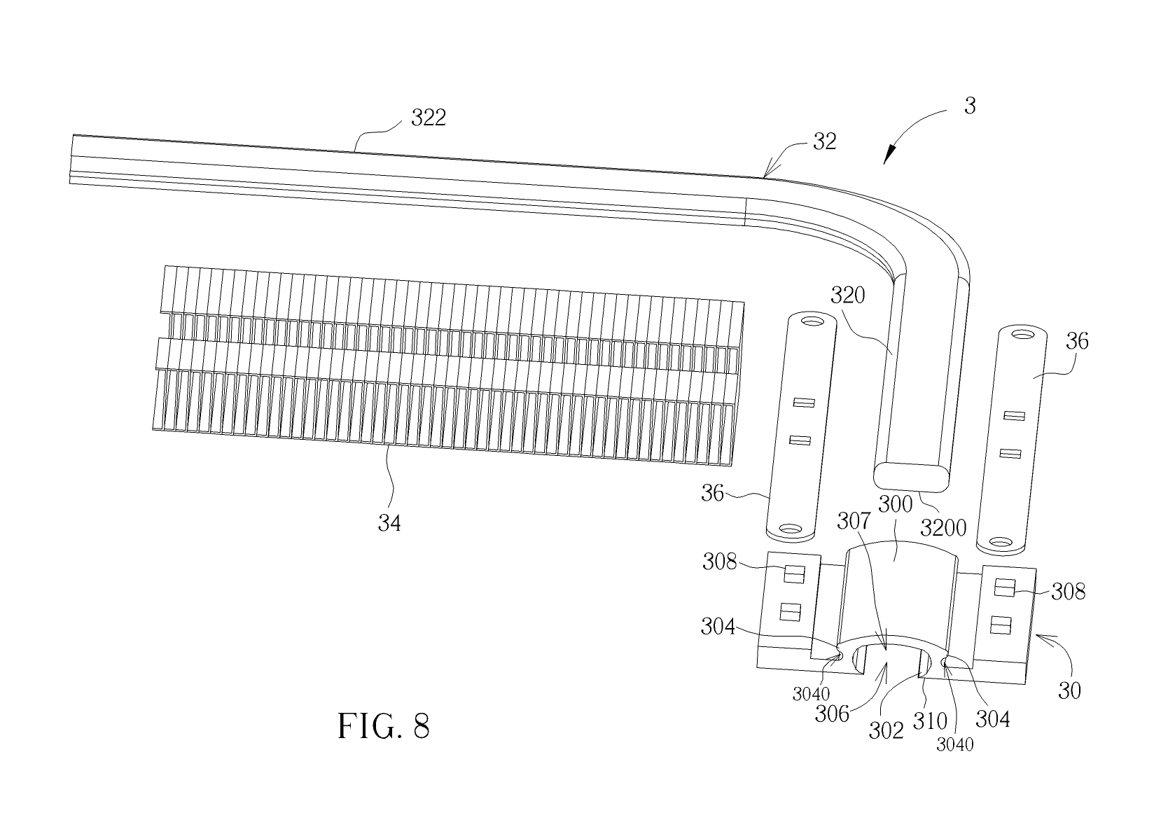

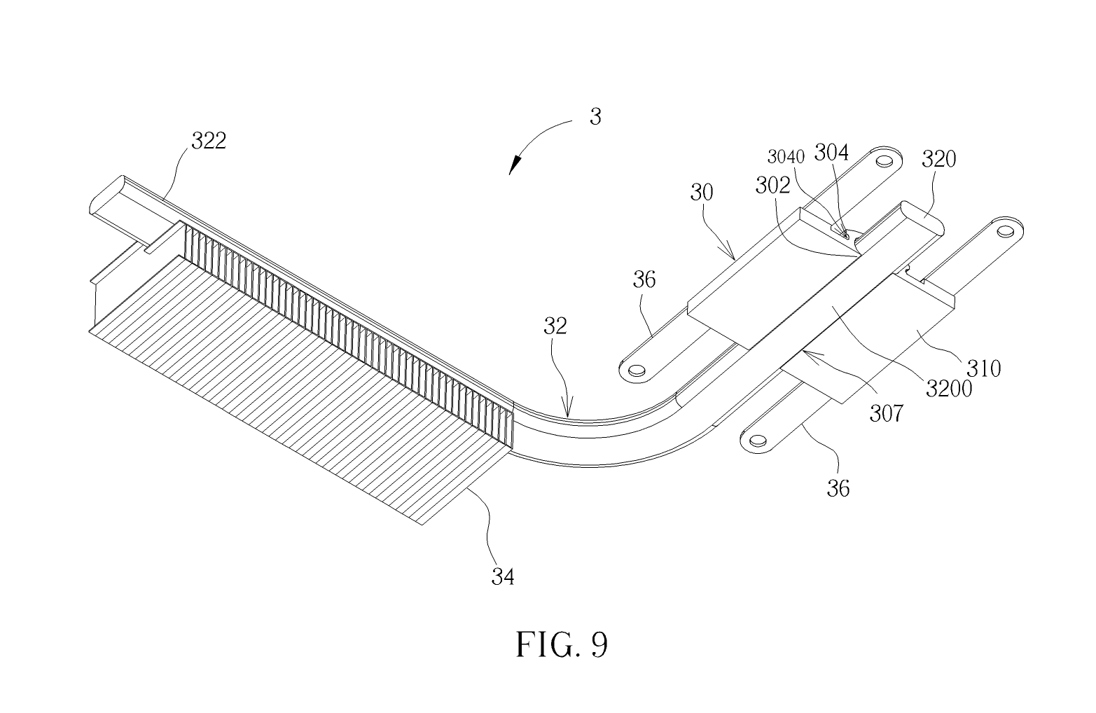

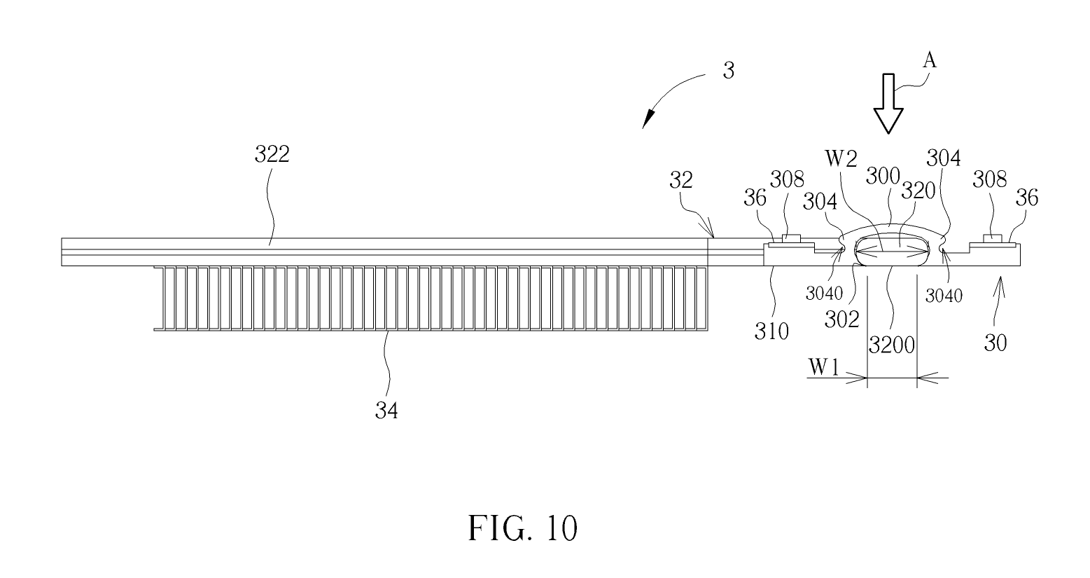

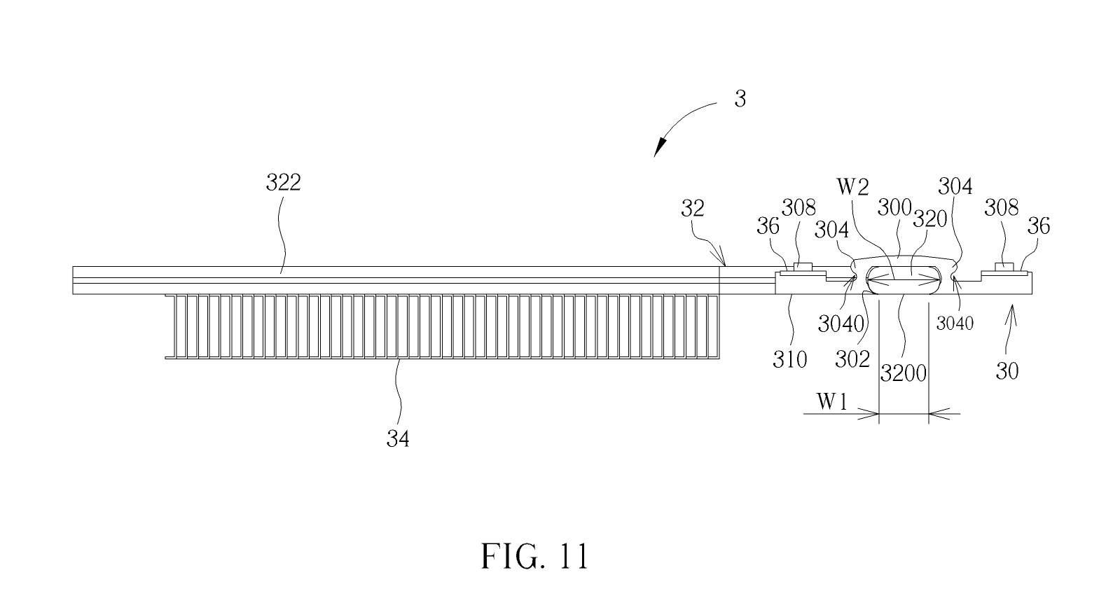

Referring to FIGS. 8 to 11, FIG. 8 is a perspective view illustrating a heat dissipating device 3 before assembly according to another embodiment of the invention, FIG. 9 is a perspective view illustrating the heat dissipating device 3 shown in FIG. 8 after assembly, FIG. 10 is a front view illustrating the heat dissipating device 3 shown in FIG. 9, and FIG. 11 is a front view illustrating a clamping portion 300 of a base 30 of the heat dissipating device 3 shown in FIG. 10 after punch processing. The method shown in FIG. 1 may be also used to manufacture the heat dissipating device 3.

First of all, step S10 is performed to provide a base 30, wherein the base 30 comprises a clamping portion 300, a supporting portion 302 and two side portions 304, the clamping portion 300 is arc-shaped, a first recess structure 3040 is formed on an outer surface toward an inner surface of each side portion 3104 such that the outer surface of each side portion 3104 is S-shaped or Z-shaped, the clamping portion 300 is opposite to the supporting portion 302, the two side portions 304 connect the clamping portion 300 and the supporting portion 302, an accommodating space 306 is formed between the clamping portion 300, the supporting portion 302 and the two side portions 304, and an opening 307 is formed on the supporting portion 302. In this embodiment, the base 30 can be formed by an aluminum extrusion process so as to simplify the manufacture process of the base 30. Accordingly, the manufacture efficiency can be improved and the manufacture cost can be reduced effectively.

Afterwards, step S12 is performed to dispose a first end 320 of a heat pipe 32 in the accommodating recess 306 of the base 30 such that the first end 320 is supported on the supporting portion 302 and dispose a heat sink 34 on a second end 322 of the heat pipe 32. At this time, a bottom surface 3200 of the first end 320 of the heat pipe 32 is exposed out of the opening 307. In this embodiment, a width W1 of the opening 307 is smaller than a maximum width W2 of the first end 320 of the heat pipe 32 such that the supporting portion 302 can support the first end 320 of the heat pipe 32 in the accommodating recess 306, so as to prevent the first end 320 of the heat pipe 32 from coming off the opening 307. In this embodiment, the heat pipe 32 is a flat heat pipe. However, in another embodiment, the heat pipe 32 may be a circular heat pipe or other heat pipes and it depends on practical applications. Furthermore, the heat sink 34 may consist of, but not limited to, a plurality of heat dissipating fins.

Step S14 is then performed to punch the clamping portion 300 of the base 30 toward the supporting portion 302 (as the direction indicated by an arrow A shown in FIG. 10) such that the clamping portion 300 deforms and cooperates with the supporting portion 302 to clamp the first end 320 of the heat pipe 32 in a tight-fitting manner, as shown in FIG. 11. Since the first recess structure 3040 is formed on the outer surface of each side portion 304, the clamping portion 300 is capable of deforming through the first recess structure 3040 during punch processing. In other words, after punching the clamping portion 300, the clamping portion 300 will extend toward the two side portions 304 so as to contact the first end 320 of the heat pipe 32 tightly. Consequently, the clamping portion 300 cooperates with the supporting portion 302 to clamp the first end 320 of the heat pipe 32 in a tight-fitting manner. In this embodiment, a thickness of the clamping portion 300 may be between, but not limited to, 0.6 mm and 1 mm such that the clamping portion 300 has high extensibility and will not crack during punch processing.

Finally, step S16 is performed to dispose two fixing members 36 on the base 30, wherein the accommodating space 306 is located between the two fixing members 36. In practical applications, the fixing members 36 may be, but not limited to, metal resilient plates. In this embodiment, the fixing members 36 may be riveted on the riveting portions 308 of the base 30. Furthermore, if there are no riveting portions 308 formed on the base 30, the fixing member 36 may be disposed on the base 30 by screws, soldering or other fixing manners.

Therefore, a heat dissipating device 3 shown in FIG. 11 can be manufactured through the aforesaid steps S10 to S16. In practical applications, the exposed bottom surface 3200 of the first end 320 of the heat pipe 32 can be attached to an electronic component (not shown) so as to dissipate heat from the electronic component. As shown in FIG. 11, after manufacturing the heat dissipating device 3, the bottom surface 3200 of the first end 320 of the heat pipe 32 and the bottom surface 310 of the base 30 may be coplanar so as to increase heat dissipating area of the heat pipe 32 and enhance stability while the heat dissipating device 3 is attached to the electronic component.

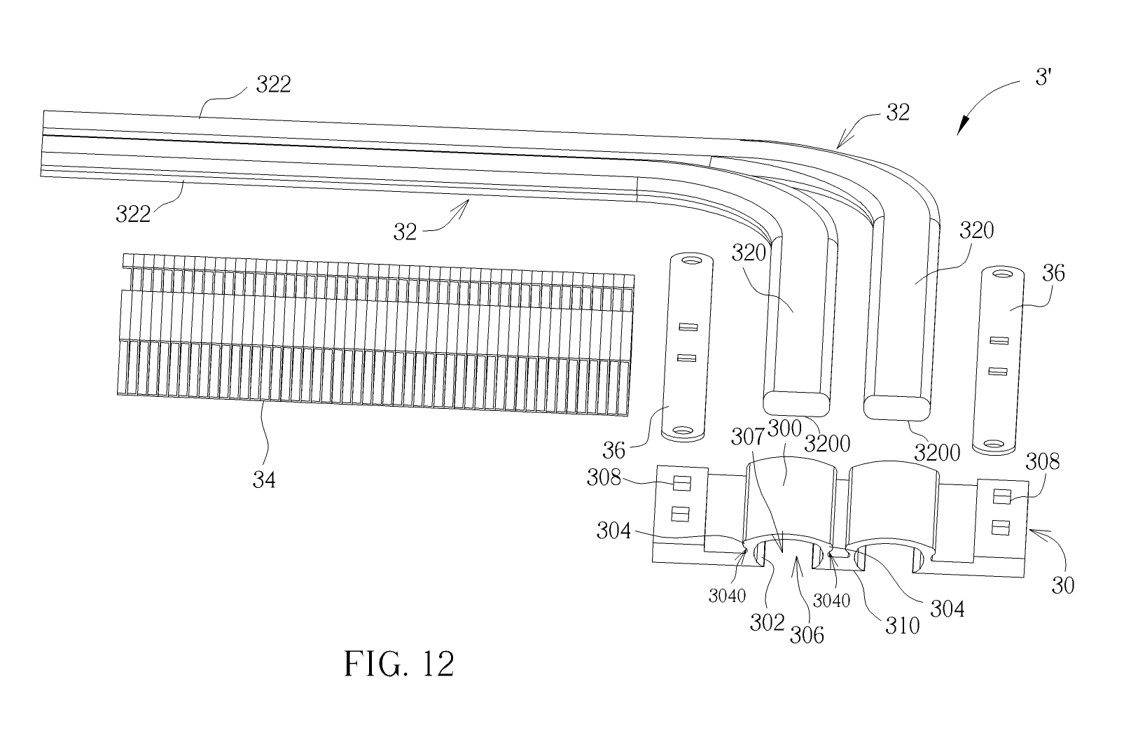

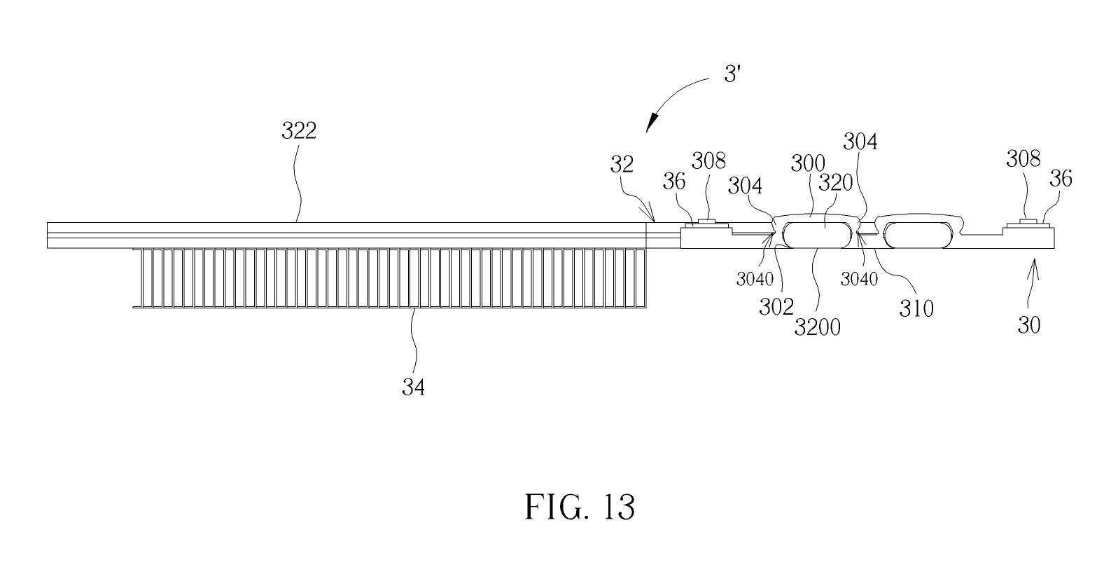

Referring to FIGS. 12 and 13 along with FIGS. 8 to 11, FIG. 12 is a perspective view illustrating a heat dissipating device 3′ before assembly according to another embodiment of the invention, and FIG. 13 is a front view illustrating the heat dissipating device 3′ shown in FIG. 6 after assembly, wherein the clamping portion 300 of the base 30′ has been punched. The difference between the heat dissipating device 3′ and the aforesaid heat dissipating device 3 is that the base 30′ of the heat dissipating device 3′ comprises two clamping portions 300, two supporting portions 302 and four side portions 304 with two accommodating spaces 306 formed therein, and the heat dissipating device 3′ comprises two heat pipes 32, as shown in FIGS. 12 and 13. The first end 320 of each heat pipe 32 can be disposed in the accommodating space 306 correspondingly through the aforesaid step S12 and then the two clamping portions 300 are punched through the aforesaid step S14, such that the two clamping portions 300 cooperate with the two supporting portions 302 to clamp the first ends 320 of the two heat pipes 32 in a tight-fitting manner, as shown in FIG. 13. In other words, the invention may form a plurality of clamping portions 300, supporting portions 302 and side portions 304 on the base 30′ by the aluminum extrusion process according to practical applications and then clamp a plurality of heat pipes 32 between the clamping portions 300 and the supporting portions 302 in a tight-fitting manner by punch processing. It should be noted that the same elements in FIGS. 12-13 and FIGS. 8-11 are represented by the same numerals, so the repeated explanation will not be depicted herein again.

As mentioned in the above, the base of the seat dissipating device of the invention can be formed by an aluminum extrusion process and the invention clamps the heat pipe in the base in a tight-fitting manner through a punch process. Since the first recess structure is formed on the outer surface toward the inner surface of each side portion, the clamping portion is capable of deforming through the first recess structure during punch processing accordingly. Furthermore, the invention may form the second recess structure on the inner surface toward the outer surface of each side portion such that the clamping portion is capable of deforming better through the second recess structure during punch processing. The process of the invention is simple and the efficiency of manufacturing the heat dissipating device can be improved effectively so that the manufacture cost can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat dissipating device comprising:
a base comprising a clamping portion, a supporting portion and two side portions, a first recess structure being formed on an outer surface toward an inner surface of each side portion, the clamping portion being opposite to the supporting portion, the two side portions connecting the clamping portion and the supporting portion, an accommodating space being formed between the clamping portion, the supporting portion and the two side portions; and
a heat pipe, a first end of the heat pipe being disposed in the accommodating space and supported on the supporting portion, the clamping portion cooperating with the supporting portion to clamp the first end of the heat pipe in a tight-fitting manner.

2. The heat dissipating device of claim 1, wherein the outer surface of each side portion is S-shaped or Z-shaped.

3. The heat dissipating device of claim 1, wherein a second recess structure is formed on the inner surface toward the outer surface of each side portion.

4. The heat dissipating device of claim 1, wherein an opening is formed on the supporting portion such that a bottom surface of the first end is exposed out of the opening, and a width of the opening is smaller than a maximum width of the first end.

5. The heat dissipating device of claim 4, wherein the bottom surface of the first end and a bottom surface of the base are coplanar.

6. The heat dissipating device of claim 1, further comprising a heat sink disposed on a second end of the heat pipe.

7. The heat dissipating device of claim 1, further comprising two fixing members disposed on the base, wherein the accommodating space is located between the two fixing members.

8. The heat dissipating device of claim 1, wherein the heat pipe is a flat heat pipe.

9. A method of manufacturing a heat dissipating device comprising:
providing a base, wherein the base comprises a clamping portion, a supporting portion and two side portions, the clamping portion is arc-shaped, a first recess structure is formed on an outer surface toward an inner surface of each side portion, the clamping portion is opposite to the supporting portion, the two side portions connect the clamping portion and the supporting portion, and an accommodating space is formed between the clamping portion, the supporting portion and the two side portions;
disposing a first end of a heat pipe in the accommodating space, wherein the first end is supported on the supporting portion; and
punching the clamping portion toward the supporting portion such that the clamping portion cooperates with the supporting portion to clamp the first end of the heat pipe in a tight-fitting manner, wherein the clamping portion is capable of deforming through the first recess structure during punch processing.

10. The method of claim 9, wherein the outer surface of each side portion is S-shaped or Z-shaped.

11. The method of claim 9, wherein a second recess structure is formed on the inner surface toward the outer surface of each side portion such that the clamping portion is capable of deforming through the second recess structure during punch processing.

12. The method of claim 9, wherein an opening is formed on the supporting portion such that a bottom surface of the first end is exposed out of the opening, and a width of the opening is smaller than a maximum width of the first end.

13. The method of claim 12, wherein the bottom surface of the first end and a bottom surface of the base are coplanar.

14. The method of claim 9, further comprising:
forming the base by an aluminum extrusion process.

15. The method of claim 9, further comprising:
disposing a heat sink on a second end of the heat pipe.

16. The method of claim 9, further comprising:
disposing two fixing members on the base, wherein the accommodating space is located between the two fixing members.

17. The method of claim 9, wherein the heat pipe is a flat heat pipe.
